(19) United States
(12) Patent Application Publication
(10) Pub. No.: US 2013/0092219 A1
(43) Pub. Date: Apr. 18, 2013

(54) SOLAR CELL

(71) Applicants: Eishi TSUTSUMI, Kawasaki-shi (JP); Kumi Masunaga, Kawasaki-shi (JP); Ryota Kitagawa, Tokyo (JP); Tsutomu Nakanishi, Tokyo (JP); Akira Fujimoto, Kawasaki-shi (JP); Koji Asakawa, Kawasaki-shi (JP)

(72) Inventors: Eishi TSUTSUMI, Kawasaki-shi (JP); Kumi Masunaga, Kawasaki-shi (JP); Ryota Kitagawa, Tokyo (JP); Tsutomu Nakanishi, Tokyo (JP); Akira Fujimoto, Kawasaki-shi (JP); Koji Asakawa, Kawasaki-shi (JP)

(73) Assignee: KABUSHIKI KAISHA TOSHIBA, Tokyo (JP)

(21) Appl. No.: 13/619,360

(22) Filed: Sep. 14, 2012

Related U.S. Application Data
(63) Continuation of application No. PCT/JP2010/002198, filed on Mar. 26, 2010.

(51) Int. Cl. H01L 31/0224

(52) U.S. Cl. CPC H01L 31/022425
USPC 136/255; 136/256

(57) ABSTRACT

The present invention provides a solar cell comprising a laminate of a photoelectric conversion layer, a metal porous membrane and a refractive index adjusting layer. The metal porous membrane is positioned on the light-incident side, is directly in contact with the photoelectric conversion layer, and has plural openings bored though the membrane. The refractive index adjusting layer covers at least a part of the surface of the metal porous membrane and of the inner surfaces of the openings, and has a refractive index of 1.35 to 4.2 inclusive. If adopting a nano-fabricated metal membrane as an electrode, the present invention enables to provide a solar cell capable of realizing efficient photoelectric conversion by use of electric field-enhancement effect.

### CROSS REFERENCE TO RELATED APPLICATIONS

This application is a continuation of International Application No. PCT/JP2010/002198, filed on Mar. 26, 2010, the entire contents of which is hereby incorporated by reference.

### TECHNICAL FIELD

This invention relates to a solar cell comprising a metal porous membrane.

### BACKGROUND ART

Solar cells directly convert inexhaustible and clean pollution-free solar energy into electrical energy, and hence they can be said to be important key devices in view of the environmental and energy exhaustion problems.

In general, a solar cell comprises a top surface electrode on the light-incident side, a counter electrode on the back side, and a semiconductor photoelectric conversion layer sandwiched between them. The photoelectric conversion layer now industrially produced is commonly made of silicon (Si), and it normally includes a PN junction of monocrystalline or polycrystalline Si or a PIN junction of amorphous Si (a-Si). In addition, as well as those using Si, solar cells using compound semiconductors such as chalcopyrite have been recently developed in advance.

At present, the largest problem of solar cells is to increase the photoelectric conversion efficiency. As a means for improving the efficiency of solar cells, there is a method in which incident sunlight is converted into other energy form suitable for photoelectric conversion. That method utilizes, for example, a phenomenon in which, if the photoelectric conversion layer comprises metal-made nanometer-scale minute structures, enhanced electric fields are generated at the edges of the minute structures to propagate carrier excitation. This phenomenon is thought to be caused by incident light that induces oscillating waves of massive electrons on metal surfaces, and those oscillating waves are said to accompany enhanced electromagnetic fields that activate carrier generation.

Actually, Patent document 1 adopts metal fine particles placed on the back side so that light in too long a wavelength range for the crystalline Si layer to convert photoelectrically can be converted into enhanced electric fields to improve the efficiency. Further, Non-Patent document 1 reports that enhanced electric currents are generated if Au nano-particles are provided on the light-receiving face of a semiconductor substrate having a pn-junction in a Si photoelectric conversion element.

### PRIOR ART DOCUMENTS

[Patent document 1] Japanese Patent Laid-Open No. 2006-66550

[Non-Patent document 1] D. M. Schaadt, APPLIED PHYSICS LETTERS 86, 063106 s2005d “Enhanced semiconductor optical absorption via surface plasmon excitation in metal nanoparticles”

### DISCLOSURE OF INVENTION

### Problem to be Solved By the Invention

However, in order to increase the enhanced electric fields in the above metal-made nano-meter-scale minute structures and thereby to generate many carriers efficiently, it is preferred that the material around the metal minute structures, that of the top surface and that of the bottom surface have similar refractive indexes (square roots of the permittivities).

For example, in the case of a crystalline Si solar cell, the photoelectric conversion layer is made of Si, whose refractive index is about 3.8 on average. Accordingly, if the metal minute structure is provided directly on the Si layer, there is a large gap in the refractive index between the Si layer and air (refractive index: 1). Because of this mismatch, conventional solar cells have a problem in which the generated electric fields have such insufficient strength that the obtained enhancement effect is not enough to improve the conversion efficiencies satisfyingly.

### Means for Solving Problems

For solving the above problem, the present invention resides in a solar cell comprising a laminate of a photoelectric conversion layer, a metal porous membrane and a refractive index adjusting layer, wherein

said metal porous membrane is positioned on the light-incident side,

said metal porous membrane is directly in contact with said photoelectric conversion layer,

said metal porous membrane has plural openings bored though said membrane,

said refractive index adjusting layer covers at least a part of the surface of said metal porous membrane and of the inner surfaces of said openings, and

said refractive index adjusting layer has a refractive index of 1.35 to 4.2 inclusive.

### Effect of the Invention

The present invention provides a solar cell in which a metal porous membrane formed on a photoelectric conversion layer is covered with a refractive index adjusting layer so that enhanced electric fields can be generated efficiently on the basis of interaction between the incident light and the metal porous membrane. Accordingly, since the generated enhanced electric fields accompany carrier excitation, the solar cell of the present invention can have high power generation efficiency.

### BRIEF DESCRIPTION OF THE DRAWINGS

FIG. 1 is a schematic sectional view of a solar cell according to an embodiment of the present invention

FIG. 2 shows results of simulation by the FDTD method carried out on the structure of Si layer/Al-made porous membrane/air in a solar cell according to an embodiment of the present invention.

FIG. 3 shows results of simulation by the FDTD method carried out on the structure of Si layer/Al-made porous membrane/Si layer in a solar cell according to an embodiment of the present invention.

FIG. 4 shows spectra of electric fields simulated by the FDTD method in the cases where refractive index adjusting layers are provided in solar cells according to embodiments of the present invention.

FIG. 5 schematically illustrates an anti-reflective coating formed on a solar cell according to an embodiment of the present invention.

FIG. 6 is an electron microscopic (SEM) image of an Al-made porous membrane provided in a solar cell according to an embodiment of the present invention when the membrane was subjected to a step of etching treatment.

FIG. 7 is an electron microscopic (SEM) image of an Al-made porous membrane provided in a solar cell according to an embodiment of the present invention when the membrane was subjected to a step of etching treatment.

FIG. 8 is an electron microscopic (SEM) image of an Al-made porous membrane provided in a solar cell according to an embodiment of the present invention when the membrane was subjected to a step of etching treatment.

FIG. 9 shows spectral sensitivity curves that indicate power generation capacities of solar cells according to embodiments of the present invention.

FIG. 10 schematically illustrates conditions for the simulation of FIG. 11 carried out on a solar cell according to an embodiment of the present invention.

FIG. 11 shows results of simulation carried out on a solar cell according to an embodiment of the present invention under the conditions illustrated in FIG. 10.

FIG. 12 shows schematic sectional views of a monocrystalline Si solar cell comprising a top surface electrode layer having fine openings according to an embodiment of the present invention.

FIG. 13 shows schematic sectional views illustrating a method of producing a metal porous membrane in a solar cell according to an embodiment of the present invention.

FIG. 14 is a schematic sectional view of a poly-crystalline Si solar cell according to an embodiment of the present invention.

FIG. 15 is a schematic sectional view of an amorphous solar cell according to an embodiment of the present invention.

FIG. 16 is a schematic sectional view of a solar cell provided with both a rough structure and a refractive index adjusting layer according to an embodiment of the present invention.

FIG. 17 shows schematic sectional views illustrating a method of producing a surface rough structure on a solar cell according to an embodiment of the present invention.

### BEST MODE FOR CARRYING OUT THE INVENTION

Embodiments of the present invention are described below.

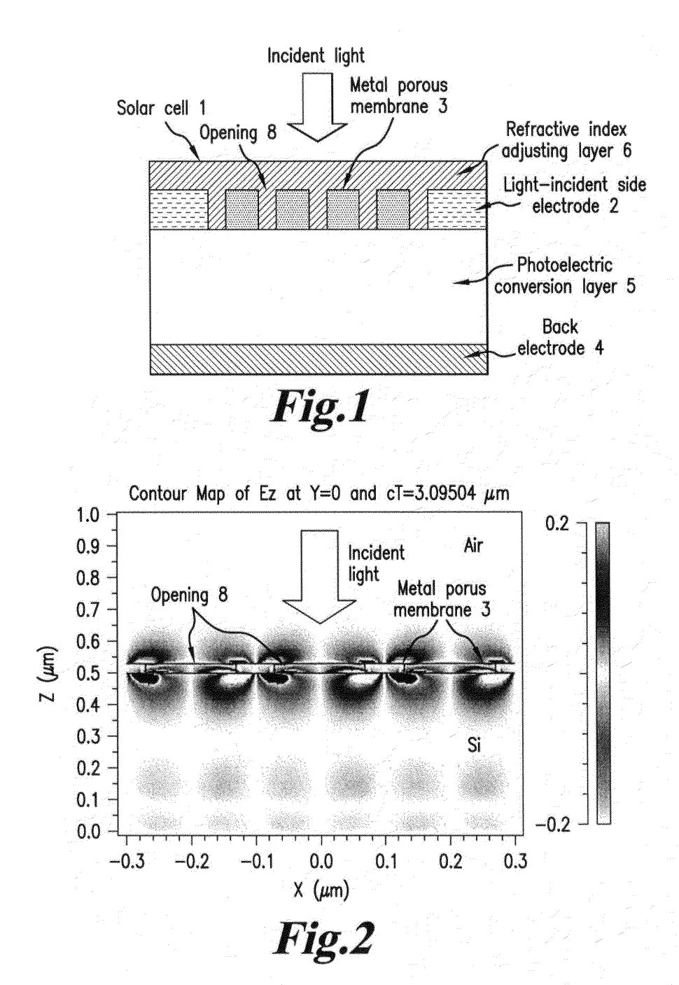

FIG. 1 is a schematic sectional view of a solar cell according to an embodiment of the present invention.

As shown in FIG. 1, the solar cell 1 according to an embodiment of the present invention comprises a light-incident side electrode 2, a metal porous membrane 3, a back-side electrode 4, and a photo-electric conversion layer 5 which is sandwiched between them and which includes semiconductor layers.

The metal porous membrane 3 is placed on the photoelectric conversion layer 5 and provided with plural openings 8 bored though the membrane. Among the plural openings 8 in the metal porous membrane 3, there is a continuous metal part almost without breaks.

Further, the metal porous membrane 3 is at least partly covered with a refractive index adjusting layer 6. The adjusting layer 6 can work if only it covers at least the surface of the porous membrane 3, but may cover also the inner surfaces of the plural openings 8.

The present inventors have found that the solar cell having the structure shown in FIG. 1 enables to increase the electric current more than expected from the amount of light received by the photoelectric conversion layer 5.

The above phenomenon can be presumed to be caused by the following mechanism. It is already known that, when the metal porous membrane 3 is exposed to light, strong electric fields are generated on the edges of the porous membrane 3 if the incident light has a wavelength comparable to the pitch among the openings 8 in the membrane 3.

Specifically, when the light-receiving surface of the metal porous membrane 3 is irradiated with light, free electrons are induced to oscillate perpendicularly to the direction of light propagation by action of the electric field-oscillating component of the incident light. Here, the “light-receiving surface” means the surface on the side where the metal porous membrane 3 is not in contact with the photoelectric conversion layer 5, while the other surface in contact is referred to as “bottom surface”. Further, the “edges of the porous membrane 3” means the boundaries between the porous membrane 3 and the openings 8 therein. When the free electrons in the membrane 3 are oscillated by the incident light, the oscillation is intercepted at the boundaries.

Since the metal porous membrane 3 has numerous openings 8, not all the free electrons can oscillate uniformly. This means that some free electrons are inhibited from oscillating by the openings 8 in the porous membrane 3. As a result, on the light-receiving surface of the membrane 3, the free electrons are densely localized at some edges but thinly populated at other edges.

In contrast, since the light penetrates into at most the skin depth, the free electrons on the bottom surface are not oscillated and accordingly are not localized. Consequently, relative density differences of the free electrons are formed at the edges between the light-incident surface and the bottom surface.

As a result, alternating electric fields oscillating parallel to the direction of light propagation are generated at the edges between the light-incident surface and the bottom surface. However, the alternating electric fields do not extend and are localized around the edges of the metal porous membrane 3. Accordingly, the energies of the local electric fields are concentrated at the edges and hence are several hundred times as strong as the energy of the electric field initially generated by the incident light. The local electric fields are thus thought to promote generation of pairs of electrons and holes.

The local electric fields at the edges of the metal porous membrane 3 are not extensive and the strength thereof exponentially decreases from the bottom surface of the membrane 3 to the inside of the conversion layer 5 in the direction parallel to light propagation. Accordingly, the photoelectric conversion layer 5 and the metal porous membrane 3 are preferably close to each other in the order of nano-meters so that the local electric fields can efficiently promote generation of pairs of electrons and holes.

With respect to the above, the present inventors have found the following three points.

(1) Effect of Refractive Index

As a result of intensive studies of the present inventors, it has been found that the electric fields are more generated in the metal porous membrane 3 to improve the photoelectric conversion efficiency when the membrane 3 formed on the conversion layer 5 of Si or the like is covered with a refractive index adjusting layer 6 so as to control the refractive index of neighborhood of the metal membrane 3, as compared with when the membrane is not covered with the refractive index adjusting layer. The principle thereof will be described below in detail.

The present inventors have found that, as described above, strong local electric fields are generated if the incident light has a wavelength matching with the pitch among the openings 8 in the membrane 3. Accordingly, the metal porous membrane 3 having openings 8 of nonometer to sub-micron sizes is placed on the photoelectric conversion layer 5, and thereby not only the light is propagated through the openings 8 but also the aforementioned strong local electric fields are generated around the openings 8 in the metal porous membrane 3.

Consequently, the present inventors have found that electric fields around the openings 8 in the metal porous membrane 3 are thus enhanced to excite numerous carriers in the photoelectric conversion layer 5 and thereby to contribute for improvement of the conversion efficiency.

In the present specification, the “refractive index” means the real part of the complex refractive index of material. The thickness of the refractive index adjusting layer 6 is determined in the following manner. If the refractive index adjusting layer 6 is too thin to measure the thickness directly, the chemical composition thereof is determined on the basis of structural analysis by SEM (scanning electron micro-scopy) or TEM (transmission electron microscopy) or of composition analysis by XPS (x-ray photoelectron spectroscopy) or SIMS (secondary ion mass spectrometry), and then the bulk of the layer substance is estimated from the obtained chemical composition and regarded as the thickness of the adjusting layer 6. On the other hand, if the refractive index adjusting layer 6 is thick enough to measure the thickness directly, the thickness is determined by means of a spectroscopic ellipsometer.

The refractive index adjusting layer 6 can work if only it covers at least a part of the metal porous membrane 3. However, the adjusting layer 6 preferably covers the light-receiving surface on the side opposite to the photoelectric conversion layer 5, and more preferably further covers the inner surfaces of the plural openings 8.

With reference to FIG. 2, the following describes strong local electric fields generated around the openings 8 in the metal porous membrane 3, by way example, in the case where the metal porous membrane 3 is made of Al. FIG. 2 shows results of simulation by the FDTD (finite diffraction time domain) method. The simulation of FIG. 2 was carried out under the following assumptions: that is, the substrate and the metal porous membrane 3 were made of Si and Al, respectively; the top surface of the membrane 3 was in contact with air; the membrane 3 had a thickness of 30 nm; the membrane 3 had openings periodically arranged; each of the openings in the membrane 3 had a size of 140 nm; the pitch among the openings was 200 nm; and the openings were aligned in a square lattice arrangement.

In FIG. 2, the vertical and horizontal axes give coordinates of positions in the metal porous membrane 3. The more thickly the positions are dotted, the stronger the electric fields are at the positions.

FIG. 2 shows the simulation results in which dots are thickly populated in the areas around the edges of the metal porous membrane 3. This indicates that the electric fields in the z component, in which the propagated light has no electric field, are enhanced at the edges of the porous membrane 3. However, in the structure of FIG. 2, there is a very large mismatch in the refractive index between the substrate Si (average refractive index: n=3.8) under the Al-made porous membrane 10 and air (refractive index: n=1.0) above the membrane 10.

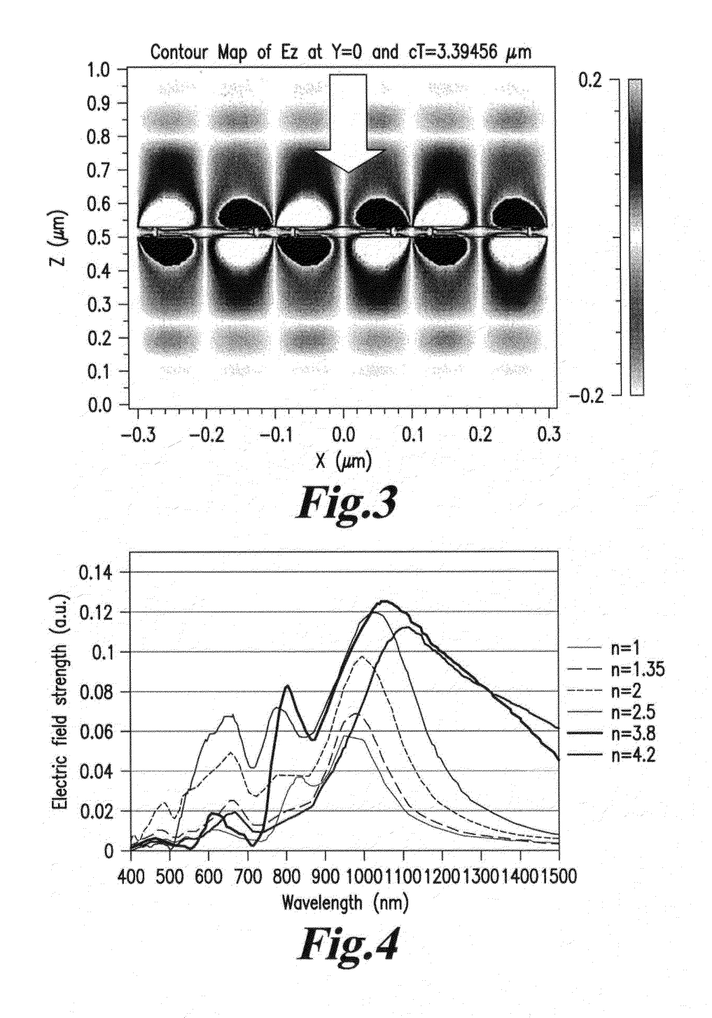

In view of the above, with reference to FIG. 3, the following describes the simulation results in the case where the openings 8 in the porous membrane 3 are filled with Si and where the top surface of the membrane 3 is completely covered with Si. The simulation of FIG. 3 was carried out under the following assumptions: that is, the substrate and the metal porous membrane 3 were made of Si and Al, respectively; the top surface of the membrane 3 was in contact with Si; the membrane 3 had a thickness of 30 nm; the membrane 3 had openings periodically arranged; each of the openings in the membrane 3 had a size of 140 nm; the pitch among the openings was 200 nm; and the openings were aligned in a square lattice arrangement.

In FIG. 3, the vertical and horizontal axes give coordinates of positions in the metal porous membrane 3. The more thickly the positions are dotted, the stronger the electric fields are at the positions.

The simulation results shown in FIG. 3 evidently indicate that dots are populated more thickly than in FIG. 2 in the areas around the edges of the metal porous membrane 3. The results thus clearly reveal that the electric fields generated at the edges are remarkably enhanced. The reason of that is presumed to be because the metal porous membrane 3 in the structure of FIG. 3 is all surrounded with Si, namely, with the substances having similar refractive indexes, in contrast with the structure of FIG. 2 in which there is a very large mismatch in the refractive index. That is thought to be why the electric fields generated at the edges are remarkably enhanced as compared with those in FIG. 2.

Further, FIG. 4 shows spectra of electric fields simulated by the FDTD method in the case where the metal porous membrane 3 on the Si substrate has openings of 100 nm diameter aligned at a pitch of 200 nm in a square lattice arrangement and where the refractive index adjusting layer 6 is provided thereon. The simulation of FIG. 4 was carried out under the assumption that the top surface of the membrane 3 was covered and the openings 8 were filled with the refractive index adjusting layer 6 of 50 nm thickness. The horizontal and vertical axes in FIG. 4 give the wave-length of incident light and the strength of electric fields, respectively. In addition, “n” in FIG. 4 represents a refractive index. FIG. 4 thus gives the results of six cases where the refractive indexes were n=1, 1.35, 2, 2.5, 3.8 and 4.2.

FIG. 4 clearly indicates that the electric fields selectively enhanced at about 1000 nm become further enhanced according as the refractive index n becomes closer to n=3.8, which is the average refractive index of Si. The electric fields thus enhanced is at most twice as strong as that of n=1. This enhancement effect is presumed to be given by matching in the refractive index among the top and bottom surfaces and the inside of the metal porous membrane 3. The electric fields enhanced in this way can excite such numerous carries as to improve the conversion efficiency.

According to the simulation results of FIG. 4, the refractive index adjusting layer 6 can function in the present invention if only it has a refractive index larger than air (refractive index n=1.0). The refractive index adjusting layer 6, therefore, can be made of any material unless it impairs the effect of the present invention. Refractive indexes of typical materials range from at least 1.35 of fluorocarbon resins to at most 4.2 of Si resins. Examples of the materials include: fluorocarbon resin, such as, polytetrafluoroethylene (PTFE) and polyvinylidene fluoride (PVDF); polymethylmethacrylate; polyvinyl chloride; polyvinylidene chloride; vinylidene acetate; polyethylene; melamine resin; nylon; polystyrene; novolac resin; and inorganic materials, such as, alumina, zirconia, SiO₂, ZnS, ZnO, TiO₂, SiN and SiC. Those materials can be also used as a coating for protecting the top surface of the solar cell from physical shocks.

The refractive index adjusting layer 6 can be formed according to known techniques, which can be freely selected from, for example, resistance heating deposition, electron beam (EB) deposition, dip-coating, spin-coating, sputtering, chemical vapor deposition (CVD), and sol-gel method.

(2) Antireflection Effect by Surface Roughness (Moth-Eye Structure)

As described above, the larger refractive index the adjusting layer 6 has, the more the enhancement effect of the electric fields can be improved. On the other hand, however, according as the refractive index of the adjusting layer 6 increases, the Fresnel reflection is inevitably enhanced at the interface between air and the refractive index adjusting layer 6. That is because the Fresnel reflection increases according to increase of difference in the refractive index at the interface.

As for the above problem, the present inventors have found that the reflection at the top surface can be prevented by use of an anti-reflective coating 7 which is formed on the top surface of the refractive index adjusting layer 6 and which has such a rough structure as comprises fine convexes or concaves at intervals shorter than the wavelength of the incident light.

The following describes the anti-reflective coating 7 which has a rough structure and which is formed on the top surface. As described above, the electric fields are strengthened if covered with a substance having a larger refractive index. On the other hand, in that case, the Fresnel reflection is enhanced at the interface between air and the refractive index adjusting layer 6.

To cope with that problem in the present invention, the reflection at the top surface is prevented by forming an anti-reflective coating 7 on the top surface of the refractive index adjusting layer 6. The anti-reflective coating has such a fine rough structure as comprises minute convexes or concaves at intervals shorter than the wavelength of the incident light.

The fine rough structure of the anti-reflective coating 7 preferably comprises minute cones or pyramids which are made of the material of the refractive index adjusting layer and are arranged at a pitch shorter than the wavelength. More preferably, the sectional shapes thereof have parabolic outlines so that the gradient index may be even to improve the antireflection effect. That is because light cannot recognize structures smaller than its wavelength and consequently acts so that the refractive index may change gradually according to the volume ratio thereof. Accordingly, the anti-reflective coating 7 having the fine rough structure makes it possible to prevent light from recognizing large difference in the refractive index and thereby from being reflected at the interface, and consequently enables the light to penetrate through the interface.

The anti-reflective structure of fine roughness is described below with reference to FIG. 5. FIG. 5 schematically illustrates an anti-reflective coating 7 which has a rough structure and which is provided on the refractive index adjusting layer 6.

As shown in FIG. 5, the light-incident side surface of the refractive index adjusting layer 6 is covered with the anti-reflective coating 7 having a rough structure comprising convexes or concaves aligned in a two-dimensionally periodic arrangement. The right drawing of FIG. 5 illustrates continuous change of the effective refractive index in the direction perpendicular to the adjusting layer 6. The convexes or concaves have two-dimensional sections of cones or pyramids, and hence, according as the horizontal level parallel to the substrate goes down perpendicularly to the adjusting layer 6, the refractive index adjusting layer 6 gradually changes its volume ratio occupying areas in the horizontal level. According as the volume ratio thus changes gradually in the vertical direction perpendicular to the adjusting layer 6, the effective refractive index also changes continuously as shown in the drawing.

In the drawing, “n1” and “n2” mean refractive indexes of air and the refractive index adjusting layer, respectively. Since the refractive index thus continuously changes in the structure of FIG. 5, light incident from air to the adjusting layer 6 does not undergo drastic change of the refractive index. Because of the continuous change in the refractive index, the light is hardly reflected and can penetrate into the refractive index adjusting layer 6.

In order to obtain the antireflection effect, the arrangement in the rough structure preferably has a period not causing diffraction of light except the 0-order diffraction. When light perpendicularly comes from air into the refractive index adjusting layer 6 of the refractive index n2, the preferred period Λ is derived from the generally known diffraction equation and is represented by:

Λ≦λ/n2 (1).

In the above formula, λ is a wavelength of the light in vacuum.

Further, the height as well as the period of the convexes is also an important factor. For the purpose of obtaining remarkable antireflection effect, the height d preferably satisfies the condition of

d≧0.25λ (2).

(3) Structural Effect in the Case Where There are Breaks in a Part of the Metal Porous Membrane

Furthermore, the present inventors have found that the power generation efficiency is further improved in the case where some of the openings 8 partly connect to each other in the metal porous membrane 3, as compared with in the case where all of them are so independently provided that any of them does not connect to another opening. Specifically, as one of the methods for producing the metal porous membrane 3, there is a process comprising the steps of: forming a mask of mesh structure on a metal membrane, and then etching the membrane through the mask according to the RIE (reactive ion etching) method. In this process, the etching treatment is normally carried out until all the openings 8 are so independently bored through the membrane that any of them does not connect to another opening. However, if the etching treatment is further continued until some of the openings 8 partly connect to each other, the power generation efficiency is found to be improved.

That is presumed to be caused by the following mechanism. Light coming into the metal porous membrane 3 can be divided into three components: that is, a component penetrating into the photoelectric conversion layer 5, a component converted into the electric fields contributing to power generation, and a component reflected and hence not contributing to power generation. If all the openings 8 are independently bored in the metal porous membrane 3, the loss by reflection is relatively large. However, if the openings 8 partly connect to each other, the reflected component decreases while the penetrating component increases. This is because, if there is a linearly continuous metal part in the porous membrane, free electrons are liable to oscillate in the continuous direction and consequently to cause, what is called, metal reflection (plasma reflection). Accordingly, if there is a break in the linearly continuous metal part, the reflection is reduced.

Further, even if some of the openings 8 are connected to each other by the etching treatment, the edges are still left in the metal porous membrane 3 and hence the aforementioned local electric fields can improve the power generation efficiency. As a result, the effect given by the local electric fields and that given by the component penetrating into the photoelectric conversion layer 5 are thought to improve the power generation efficiency cooperatively.

For the reason described above, the metal porous membrane 3 is not necessarily limited to a metal membrane provided with numerous openings 8. The openings 8 may connect to each other, or there may be a metal island in each opening.

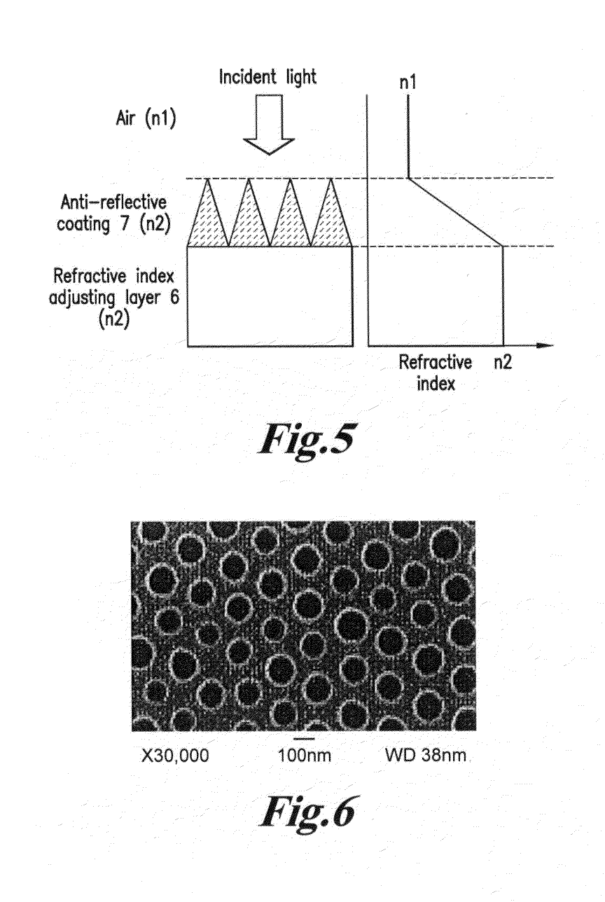

FIGS. 6 to 8 are electron microscopic (SEM) images of an Al-made membrane subjected to the process in which the membrane on the light-incident side is coated with a SOG (spin-on-glass) mask in a mesh shape and then etched through the mask. Accordingly, the electron microscopic (SEM) images of

FIGS. 6 to 8 show an Al membrane whose Al is gradually etched away to form a porous membrane. FIG. 9 shows spectral sensitivity curves that indicate power generation capacities of the solar cells produced by use of the shown membranes. The horizontal and vertical axes in FIG. 9 give the wavelength of incident light and the spectral sensitivity, respectively.

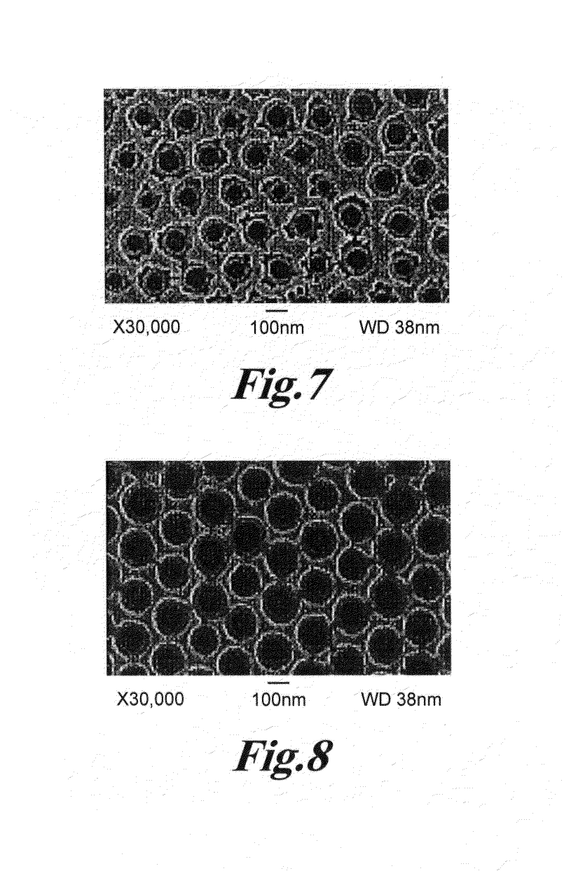

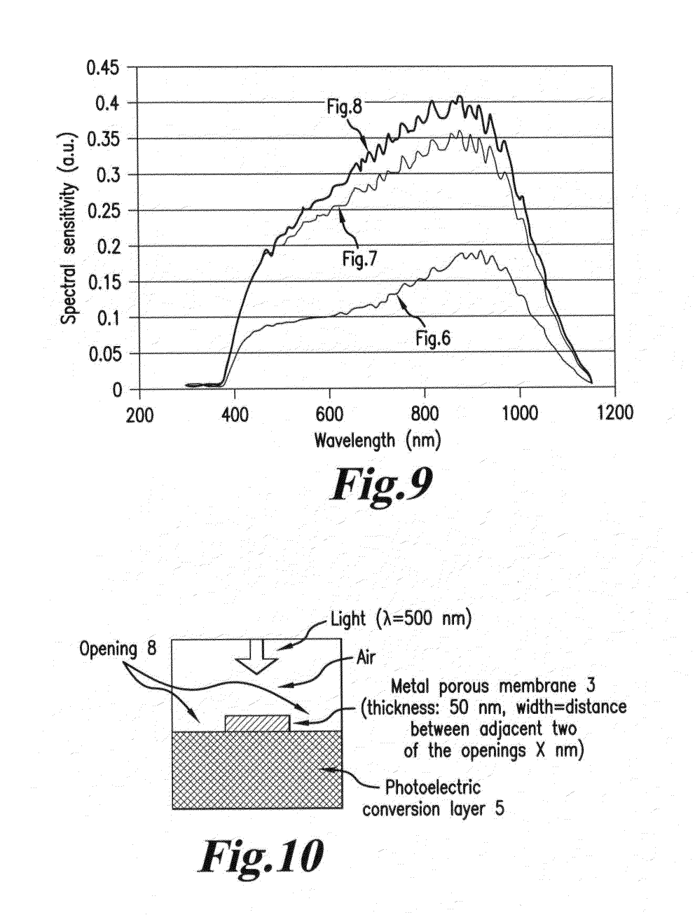

The etching time was gradually prolonged until a complete mesh structure was formed as shown in FIG. 6. However, even though the complete mesh structure was thus obtained, the power generation efficiency was still relatively low as shown in FIG. 9. On the other hand, the etching treatment was further continued until breaks began to appear in some parts of the mesh structure as shown in FIGS. 7 and 8. The obtained solar cells showed remarkably improved power generation efficiencies as shown in FIG. 9. This is presumed to be because, as described above, the penetrating light component is reflected in the case of only the complete mesh structure. However, in the case of the mesh structure including breaks, the penetrating light component contributes to the power generation efficiency cooperatively with the effect of the electric fields given by the metal porous membrane 3. Accordingly, the metal porous membrane 3 of the present invention not necessarily has a complete mesh structure, and preferably has breaks in some parts.

In the above, the methods for improving the efficiency are described in detail. However, in order to obtain the above-described effects sufficiently, it is necessary to select properly various conditions such as the sizes and shapes of the openings 8, the pitch among them, the thickness of the metal porous membrane 3 and the like. Accordingly, the following describes the optimal conditions of various parameters.

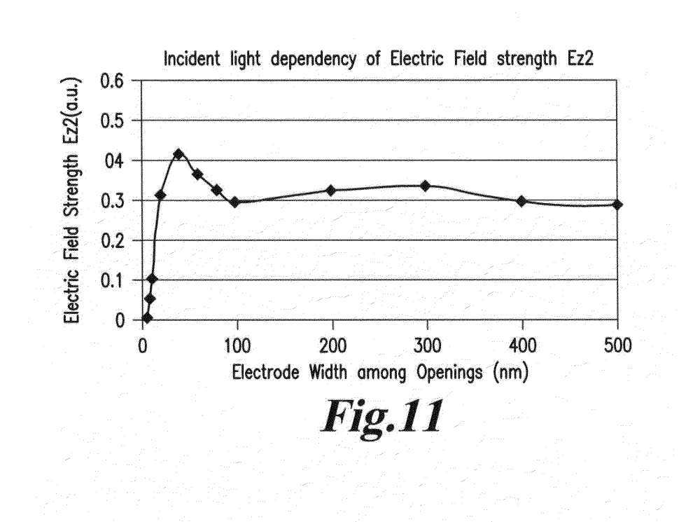

In the metal porous membrane 3, the width between adjacent two of the openings 8 has a relation to the strength of the local electric fields generated at the edges. With reference to FIGS. 10 and 11, the relation between the width and the electric field strength is described below. FIG. 10 schematically illustrates conditions for the simulation of FIG. 11, and FIG. 11 shows results of simulation carried out under the conditions illustrated in FIG. 10. The horizontal and vertical axes in FIG. 11 give the metal width among the openings 8 and the strength of electric fields, respectively.

As shown in FIG. 10, the simulation of FIG. 11 was carried out under the following assumptions: that is, the metal porous membrane 3 had a thickness of 50 nm; the distance between adjacent two of the openings was represented by X nm; and the light had a wave-length of 500 nm.

FIG. 11 shows that the curve of the electric field strength has a peak within the range where the width of the metal porous membrane 3 is 10 nm to 200 nm inclusive. This is because, if the metal width is less than 10 nm, the metal part in a linear shape contains free electrons so insufficiently that dipoles generated at both ends of the linear metal part are too small to obtain the electric field-enhancement effect. On the other hand, if the width of the metal porous membrane 3 is more than 200 nm, the dipoles do not interact with each other to give a constant value of electric field strength.

In the metal porous membrane 3 proposed in the present invention, the narrowest metal part between adjacent two of the openings 8 separates them in a distance of preferably not less than 10 nm and less than 200 nm on average. The average distance is more preferably not less than 25 nm so that the free electrons may not be prevented from oscillating in the metal part. Further, the average distance is also preferably not more than 100 nm so as not to increase reflection by the metal part.

In a solar cell of the present invention, the metal porous membrane 3 may serve as a top electrode of the photoelectric conversion layer 5. In that case, for the purpose of ensuring high conductivity, the opening ratio of the openings 8 needs to be in the range of 10% to 66% inclusive in the metal porous membrane 3. Further, at least 50% or more by volume of the metal porous membrane 3 is preferably occupied by a metal part so continuous that any pair of point-positions in the part is continuously connected without breaks.

As long as the metal part has such a width that the dipoles generated at both ends are not cancelled out by each other in the metal porous membrane 3, the electrode preferably contains many edges of the porous membrane 3 in view of the electric field-enhancement rate per unit area. Accordingly, if the opening diameter is a constant value, the shorter intervals the openings 8 are arranged at, the more the electric fields are enhanced. On the other hand, if there are two porous membranes whose openings are arranged at the same intervals but have different diameters, for example, 1000 nm and 500 nm, the membrane of 500 nm diameter has more openings per unit area than that of 1000 nm diameter and hence gives stronger electric field-enhancement.

However, as long as the porous membrane contains many edges per unit area, the openings are not necessarily arranged periodically. Even if they are arrange pseudo-periodically or randomly, the effect of the present invention can be obtained. There are, therefore, no particular restrictions on the arrangement of the openings 8 in the present invention. Further, the shapes of the openings 8 are also not restricted to circles.

In the case where the openings 8 are circles in shape, the opening diameter is preferably 5 nm to 500 nm inclusive. Even if the openings 8 are not circles in shape, each opening preferably occupies an area of 80 nm² to 0.8 μm² inclusive.

In the embodiment of the present invention, the metal porous membrane 3 is preferably thick enough to induce electric fields. If the thickness is less than 2 nm, weak local electric fields are generated because difference in the electron density is small between the light-receiving surface and the bottom surface in the metal porous membrane 3. On the other hand, if the thickness is more than 200 nm, weak local electric fields are also generated because the electric field of light cannot reach to the bottom surface. Accordingly, the metal porous membrane 3 preferably has a thickness of 2 nm to 200 nm inclusive.

If being too thin to produce evenly, the membrane may have such defects as make it difficult to obtain the effect of the present invention sufficiently.

Accordingly, the metal porous membrane 3 more preferably has a thickness of 25 nm or more. Further, in consideration of the carrier excitation given by the electric fields, the thickness of the porous membrane 3 is also preferably 100 nm or less.

In the above, the constitution of a solar cell according to an embodiment of the present invention is described from the structural aspect. However, the materials thereof can be freely selected from known substances.

The metal porous membrane 3 in the present invention can be made of any known metal, which can be freely selected to use. Here, the “metal” means a material which is an electroconductive simple substance, which has metallic gloss, which has malleability, which consists of metal atoms and which is solid in room temperature; or an alloy thereof. Since the electric field-enhancement effect is induced by penetration of electromagnetic waves into the metal porous membrane 3, the metal minute structure in an embodiment is preferably made of materials less absorbing light in the wavelength range intended to be used.

Examples of the material include aluminum, silver, gold, platinum, nickel, cobalt, chrome, copper and titanium. Preferred are aluminum, silver, gold, platinum, nickel and cobalt. However, other metals can be used as long as they have metallic gloss.

At present, the photoelectric conversion layer 5 is most popularly made of p-type and n-type semi-conductors. In order to produce the layer easily and inexpensively, it is necessary to use p-type and n-type semiconductors. As the semiconductors, Si is preferred because it can be easily available. For example, monocrystalline Si, polycrystalline Si and amorphous Si can be adopted.

The structure of the photoelectric conversion layer 5 is not restricted to a two-layer laminate of n-and p-layers, and may be a Schottky barrier junction or a PIN junction. In the present invention, there are no particular restrictions on the structure of the photo-electric conversion layer 5.

Further, the present invention can be combined with surface fabrications applied to the anti-reflective coating 7 or to the bottom surface of the photoelectric conversion layer 5 for the purpose of improving the conversion efficiency. The present invention, therefore, by no means restricts the improvement on the photo-electric conversion layer 5.

The light-incident side electrode and the back electrode 4 may be made of any material as long as it can have an ohmic contact with the contiguous semi-conductor. For example, Ag, Al and Ag/Tl are popularly used. Further, transparent electrodes may be adopted. Meanwhile, there are various attempts for improving the efficiency. For example, the surface of the photoelectric conversion layer 5 on the light-incident side may be coated with an antireflective coating 7, and/or the top or bottom surface of the photoelectric conversion layer may be improved by use of texture etching or BSF (back surface field). Those improvements can be applied to the solar cell according to an embodiment of the present invention, unless they impair the effects of the invention.

### EXAMPLES

The present invention is further explained by use of the following examples, but they by no means restrict the present invention.

### Example 1

### Monocrystalline Si Solar Cell

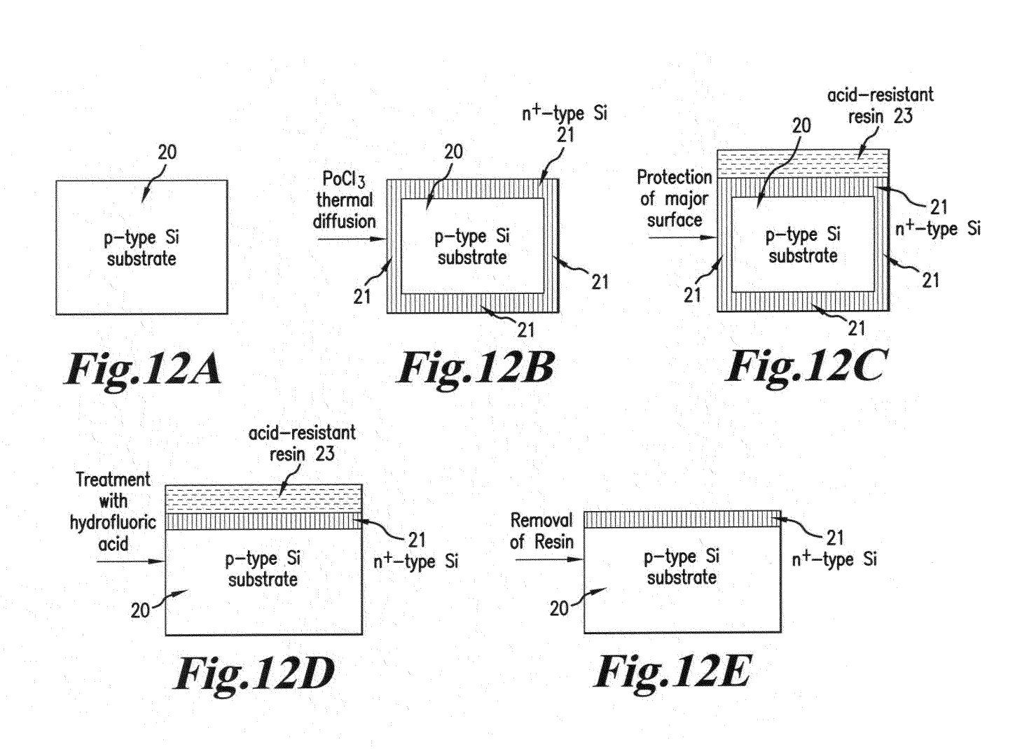

With reference to FIG. 12, Example 1 describes a process of producing a monocrystalline Si solar cell and properties thereof.

FIG. 12 shows schematic sectional views of a monocrystalline Si solar cell comprising a top surface electrode layer provided with fine openings according to an embodiment of the present invention.

First, the following will explain the process of producing a photoelectric conversion layer 5 of mono-crystalline Si.

In the first step, a p-type silicon substrate 20 made of p-type monocrystalline silicon was prepared as the semiconductor substrate, as shown in FIG. 12(a).

The semiconductor substrate in the present example was obtained by slicing a silicon ingot in a thickness of 540 μm. The silicon ingot was doped with boron and grown by the Czochralski process. The sliced ingot was then mechanically polished to obtain a p-type silicon substrate 20 which had a thickness of 380 μm and which was made of p-type monocrystalline silicon having a specific electrical resistance of about 8 Ω·cm. However, in the present invention, the semi-conductor substrate may be made of polycrystalline silicon.

Subsequently, as shown in FIG. 12(b), an n⁺-layer 21 containing an n-type impurity element such as phosphorus in a large amount was provided on one major surface of the p-type silicon substrate 20. The n⁺-layer 21 can be formed according to the thermal diffusion process in which the p-type silicon substrate 20 is placed in a high-temperature gas atmosphere containing phosphorus oxychloride (POCl₃) so as to diffuse the n-type impurity element such as phosphorus into the major surface of the substrate 20. When thus intended to be formed on one major surface according to the thermal diffusion process, the n⁺-layer 21 is often also formed on the ends and on the other major surface of the p-type silicon substrate 20.

In Example 1, the p-type silicon substrate 20 was placed in a POCl₃ gas atmosphere at 1100° C. for 15 minutes to form an n⁺-layer 21 on the substrate 20 according to the thermal diffusion process. The formed n⁺-layer 21 was found to have a sheet resistance of about 50 Ω/square.

Next, as shown in FIG. 12(c), the n⁺-layer 21 thus formed on the both surfaces and ends of the p-type silicon substrate 20 was selectively covered with an acid-resistant resin 22 in the area needed to remain.

After the acid-resistant resin 22 was thus placed on the n⁺-layer 21, the p-type silicon substrate 20 was immersed in a hydrofluoric-nitric acid solution for 15 seconds so as to remove the n⁺-layer 21 in the area not covered with the acid-resistant resin 22, as shown in FIG. 12(d). In the manner of this procedure, the n⁺-layer 21 in the area not needed to remain can be removed by immersing the p-type silicon substrate 20 in a hydrofluoric-nitric acid solution.

Successively, the acid-resistant resin 22 was removed to provide the n⁺-layer 21 only on one major surface of the p-type silicon substrate 20, as shown in FIG. 12(e). The n⁺-layer 21 thus provided had a thickness of about 500 nm.

Further, Au/Zn was vapor-deposited in vacuum on the major surface of the p-type silicon substrate 20, to form a back electrode 4. The formed Au/Zn layer served as both a back electrode and a reflective coating.

Thereafter, a metal porous membrane 3 having fine openings was formed on the sunlight-receiving surface of the n⁺-layer 21.

Meanwhile, the present inventors have found a method of forming a mono-particle layer in which nano-particles are aligned in a closest packing arrangement on a substrate. Further, the present inventors have also found a method in which the aligned nano-particles are slimed down to desired sizes by etching so as to produce a dot pattern. The dot pattern is transferred onto the metal porous membrane 3 on the photoelectric conversion layer 5 in the manner described later, to form an electrode layer having openings.

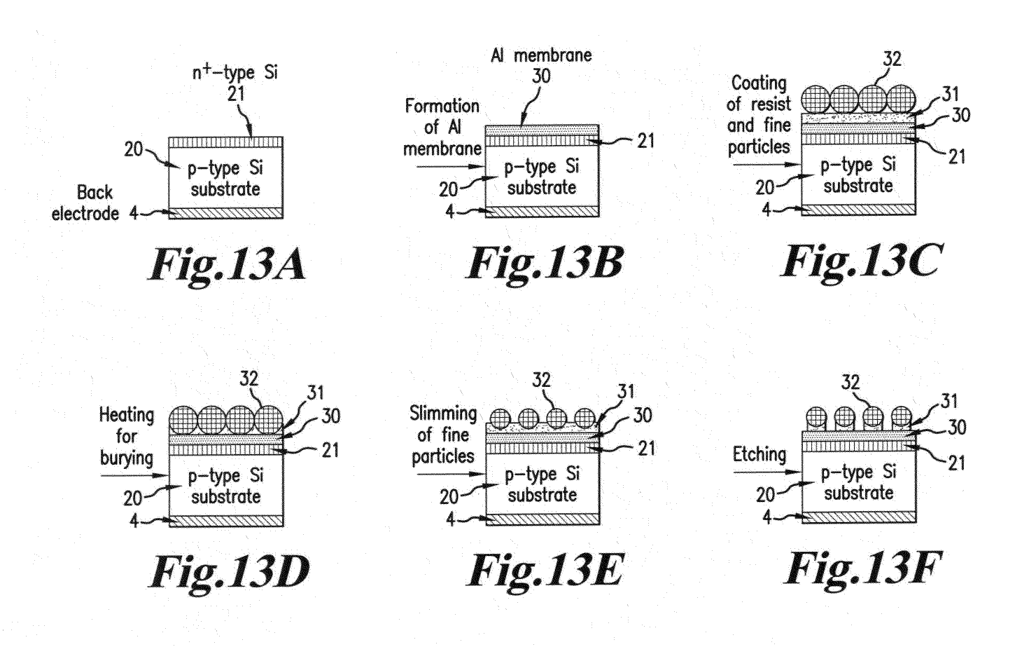

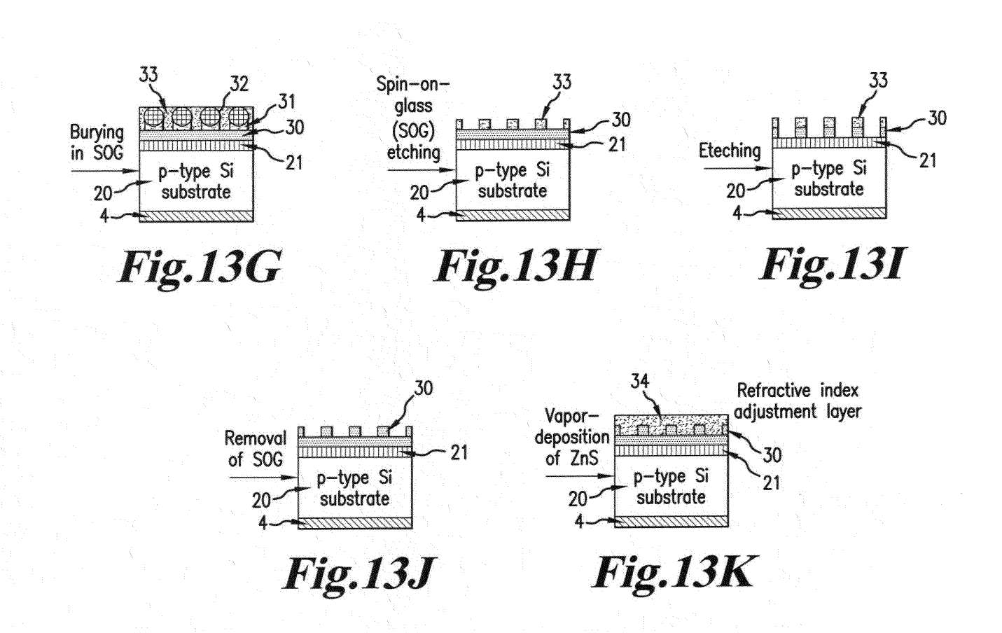

The following describes a process of producing the metal porous membrane 3 with reference to FIG. 13.

FIG. 13 shows schematic sectional views illustrating a method of producing a metal porous membrane in a solar cell according to an embodiment of the present invention.

In this example, as the metal porous membrane 3 having fine openings, an Al-made porous membrane was formed on the n⁺-layer 21. FIG. 13 shows concrete procedures for forming an Al-made porous membrane 10 serving as a top surface electrode having fine openings.

First, as shown in FIGS. 13(a) and (b), Al was vapor-deposited in vacuum on the major surface of the n⁺-layer 21 on the p-type silicon substrate 20, to form an Al membrane 30 of 50 nm thickness.

Independently, an i-ray positive-working thermo-setting resist (THMR IP3250 [trademark], manufactured by Tokyo Ohka Kogyou Co., Ltd.) was diluted with ethyl lactate by 1:1 and then filtrated through a 0.2 μm-mesh filter to prepare a solution. The solution was spin-coated on the Al membrane 30 at 2000 rpm for 60 seconds to form a resist layer 31. The layer was then heated on a hot-plate at 110° C. for 90 seconds, and further heated at 270° C. for 1 hour in an oxidation-free inert oven under a nitrogen atmosphere to undergo a thermosetting reaction. The resist layer 31 thus formed had a thickness of approx. 240 nm

The resist layer 31 was then subjected to reactive etching for 3 seconds under the conditions of O₂: 30 sccm, 100 mTorr and a RF power of 100 W by means of a reactive etching system (RIE-200L [trademark], manufactured by SAMCO Inc.), and thereby the resist layer on the top surface was hydrophilized to improve the wettability in the following coating procedure.

Subsequently, as shown in FIG. 13(c), a dispersion solution of fine silica particles 32 having a size of 200 nm (PL-13 [trademark], manufactured by Fuso Chemical Co., Ltd.) was diluted with an acrylic polymer to 5 wt %, and filtrated through a 1 μm-mesh filter to prepare a coating solution of fine silica particle dispersion. The solution was spin-coated at 2000 rpm for 60 seconds on the above resist-coated substrate.

Further, as shown in FIG. 13(d), the fine silica particles 32 provided by spin-coating were then annealed at 150° C. for 1 hour in an oxidation-free inert oven under a nitrogen atmosphere. As a result of the procedure of FIG. 13(d), only the fine silica particles 32 aligned in the bottom are made to sink into the resist layer hydrophilized in the previous procedure. After that, the substrate was cooled to room temperature and thereby the resist layer 31 was hardened again so that only the particles 32 aligned in the bottom were captured in the substrate surface.

Thereafter, as shown in FIG. 13(e), the fine silica particles 32 were subjected to etching for minutes under the conditions of CF₃: 30 sccm, 10 mTorr and a RF power of 100 W. The procedure of FIG. 13(e) reduced the size of the particles to expand intervals among them. The etching conditions were so selected that the underlying resist layer 31 might not undergo the etching. After the above procedure of FIG. 13(e), the particles were observed by means of an electron microscope (JSM-6300S [trademark], manufactured by JEOL Ltd.), to find that the size of the fine silica particles 32 and the intervals among them were about 120 nm and about 80 nm, respectively.

Subsequently, as shown in FIG. 13(f), the remaining silica particles 32 were used as an etching mask while the underlying thermosetting resist layer 31 was subjected to etching for 270 seconds under the conditions of O₂: 30 sccm, mTorr and a RF power of 100 W. As a result, columnar structures of high aspect ratios were formed in the areas where the etched silica particles 32 had been previously positioned, to obtain a pillar resist pattern of high aspect ratios.

Independently, a solution of spin-on-glass 33 (hereinafter, referred to as SOG) (SOG-5500 [trade-mark], manufactured by Tokyo Ohka Kogyou Co., Ltd.) was diluted to 14 wt % with ethyl lactate and then filtrated through 0.3 μm-mesh filter. The obtained SOG solution was then spin-coated at 2000 rpm for 40 seconds on the resist pattern comprising the fine silica particles 32 and the resist layer 31, as shown in FIG. 13(g). After that, the formed SOG layer 33 was heated on a hot-plate at 110° C. for 90 seconds and further heated at 250° C. for 1 hour in an oxidation-free inert oven under a nitrogen atmosphere.

The SOG layer 33 formed in the procedure of FIG. 13(e) and the slimed fine silica particles 32 included therein were then etched for 11 minutes under the conditions of CF₃: 30 sccm, 10 mTorr and a RF power of 100 W, and thereby the SOG 33 on the resist layer 31 and the fine silica particles 32 were removed to form the SOG layer 33 in a hole-pattern shape on the substrate surface, as shown in FIG. 13(h). The remaining pillars of thermosetting resist 31 were then etched for 150 seconds under the conditions of O₂: 30 sccm, 10 mTorr and a RF power of 100 W. Thereafter, as shown in FIG. 13(i), the Al membrane 30 was etched through the SOG layer 33 as a mask by means of ICP-RIE system (manufactured by SAMCO Inc.). In general, when an aluminum film is exposed to air, a few nonometer-thick AlO₃ layer is immediately formed thereon. Therefore, the Al membrane 30 was first subjected to sputter-etching for 1 minute under the conditions of Ar: 25 sccm, 5 mTorr, an ICP power of 50 W and a Biass power of 150 W to remove Al₂O₃, and was then successively etched for 50 seconds under the conditions of Cl₂/Ar mixed gas: 2.5/25 sccm, 5 mTorr, an ICP power of 50 W and a Biass power of 150 W.

Subsequently, as shown in FIG. 13(j), the remaining SOG layer 33 was removed by etching for 150 seconds by means of a reactive etching system under the conditions of CF₄: 30 sccm, 10 mTorr and a RF power of 100 W.

The procedures of FIGS. 13(a) to (j) gave a 50 nm-thick Al-made porous membrane 10 on the n⁺ layer 21. The Al-made porous membrane 10 was thus provided with openings having an average opening area of 4.0×10⁻² μm² (opening diameter: 113 nm) and an average opening ratio of 30.3%. The transmittance of the produced Al-made porous membrane 10 was measured at an incident light wavelength of 500 nm, and found to be about 60%. The resistivity thereof was also found to be about 107.3 μΩ·cm.

On the solar cell thus produced by the procedures of FIGS. 13(a) to (j), ZnS (refractive index: about 2.4) was vapor-deposited to accumulate in vacuum to form a refractive index adjusting layer 34 of 50 nm thickness, as shown in FIG. 13(k). The top surface of the obtained solar cell was covered with ZnS, which was accumulated even in the inside of the openings. The produced solar cell was exposed to pseudo-sunlight of AM 1.5, to evaluate properties at room temperature by use of a solar simulator. As a result, the efficiency was found to be as high as 7.2%.

### Comparative Example 1

The procedures of Example 1 were repeated except for not accumulating ZnS, to produce a solar cell. The produced solar cell was exposed to pseudo-sunlight of AM 1.5, to evaluate properties at room temperature by use of a solar simulator. As a result, the efficiency was found to be 6.1%.

### Example 2

### Polycrystalline Si Solar Cell

This example describes a process of producing a polycrystalline Si solar cell comprising the metal porous membrane 3 serving as an electric field enhancing layer, and properties thereof are also explained below.

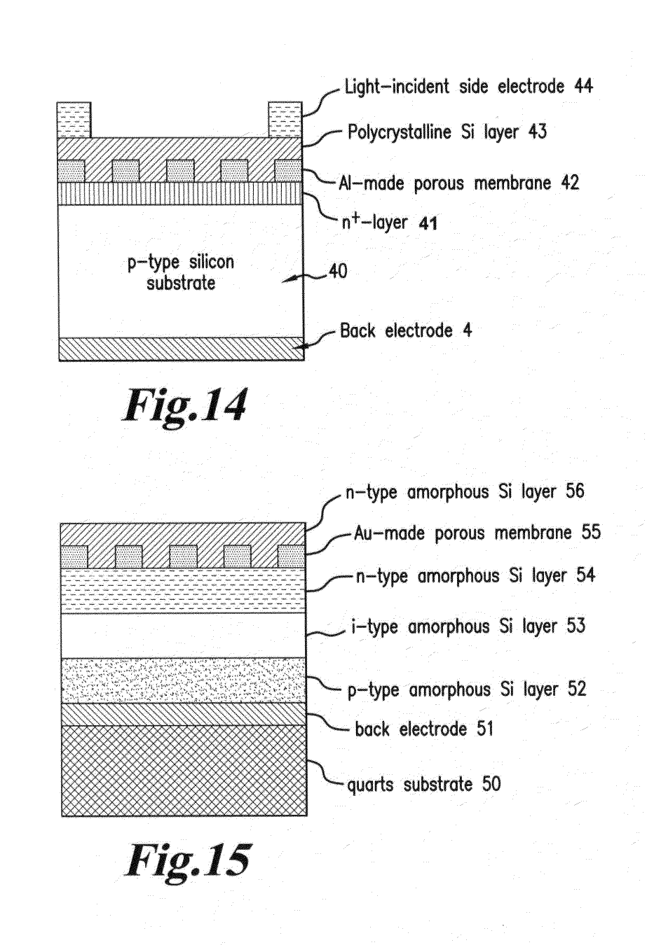

FIG. 14 shows a schematic sectional view of a polycrystalline Si solar cell according to an embodiment of the present invention. The process of producing the polycrystalline Si solar cell is similar to that in Example 1, and hence drawings thereof are omitted.

First, a B-doped p-type polycrystalline Si substrate (B dope: 10¹⁵ atom/cm³, thickness: 300 μm) 40 produced by the cast process was prepared as the semiconductor substrate. In this embodiment, generally known impurities other than boron may be doped and it is also possible to prepare an n-type substrate, on which a p-layer may be thereafter formed.

Next, in the same manner as in Example 1, an n⁺-layer 41 doped with P was formed on the top surface of the p-type Si substrate 40 by use of phosphorus oxychloride (POCL₃).

Subsequently, a metal porous membrane 3 was formed on the p-type Si substrate 40. In Example 2, an Al-made porous membrane 42 was produced in the following manner. First, Al was vapor-deposited in vacuum on the major surface of the p-layer on the p-type Si substrate 40 to form an Al-made porous membrane 42 of 30 nm thickness.

The Al-made porous membrane 42 deposited on the substrate was spin-coated with an i-ray positive-working thermosetting resist, and then annealed in a nitrogen atmosphere at 270° C. for 1 hour to make the thermosetting reaction proceed and thereby to form a resist layer of about 240 nm thickness.

Independently, a dispersion solution containing fine silica particles of 200 nm diameter (PL-13 [trade-mark], manufactured by Fuso Chemical Co., Ltd.) was diluted to 5 wt. % with a composition containing acrylic monomers, and then filtered to remove secondary particles. The obtained dispersion solution of fine silica particles was spin-coated at 2000 rpm for 60 seconds on the above resist layer formed on the substrate, and annealed in a nitrogen atmosphere at 150° C. for 1 hour. After that, the substrate was cooled to room temperature, and thereby a regularly arranged monoparticle layer of fine silica particles was formed on the above hydrophilized resist layer. In the present example, fine silica particles were adopted as the fine particles. However, fine particles of any organic or inorganic material can be used as long as they can realize the below-described unevenness of etching rate. The size of the fine particles is determined according to the opening size on the porous membrane 3 intended to be produced, but generally is 60 to 700 nm.

The monoparticle layer of fine silica particles was then etched for 20 seconds under the conditions of O₂: 30 sccm, 10 mTorr and a RF power of 100 W, to remove excess of the acrylic substance. Successively, the monoparticle layer was etched for minutes under the conditions of CF₄: 30 sccm, 10 mTorr and a RF power of 100 W. The results were observed by electron microscopy, and consequently it was found that the silica particles had diameters of about 120 nm and that the interval among them was about 80 nm.

Subsequently, the underlying thermosetting resist layer was etched for 270 seconds by use of the remaining fine silica particles as a mask under the conditions of O₂: 30 sccm, mTorr and a RF power of 100 W. As a result, pillar structures of high aspect ratios were formed in the area where the silica particles had been positioned in the early steps, to obtain a pattern of pillars.

The obtained pillar resist pattern was then spin-coated with spin-on-glass (SOG-14000 [trade-mark], manufactured by Tokyo Ohka Kogyou Co., Ltd.), and annealed in a nitrogen atmosphere at 250° C. for 1 hour. In this way, the gaps among the pillars of the resist pattern were filled with SOG.

Thereafter, the SOG layer formed in the previous step and the slimed fine silica particles buried therein were etched for 11 minutes under the conditions of CF₄: 30 sccm, 10 mTorr and a RF power of 100 W, so that the SOG and silica particles lying on the pillar resist pattern were removed to form a composite of the pillar resist pattern and the SOG filling in the gaps among the pillars.

The thermosetting resist in pillar shapes was then etched for 150 seconds under the conditions of O₂: 30 sccm, 10 mTorr and a RF power of 100 W, to form a SOG mask on the Al-made porous membrane 42. The SOG mask had a pattern in reverse to the above pillar resist pattern.

Successively, the Al-made porous membrane 42 was etched through the obtained SOG mask by means of an ICP-RIE apparatus (manufactured by SAMCO Inc.) in the following manner. First, the Al membrane was subjected to sputter etching for 1 minute under the conditions of Ar: 25 sccm, 5 mTorr, an ICP power of 50 W and a Bias power of 150 W, to remove a naturally oxidized thin layer of AlO₃ formed on the surface. Thereafter, the Al membrane was further etched for 50 seconds by use of a Cl₂/Ar mixed gas (Cl₂/Ar: 2.5/25 sccm) under the conditions of 5 mTorr, an ICP power of 50 W and a Bias power of 150 W.

Furthermore, the etching procedure was carried out by means of the reactive etching apparatus for 150 seconds under the conditions of CF₄: 30 sccm, 10 mTorr and a RF power of 100 W, to remove the remaining SOG mask.

The above procedures gave an Al-made porous membrane 42 on the p-layer. The formed porous membrane had a thickness of 30 nm and was provided with openings having an average opening area of 9.8×10⁻³ μm² (opening diameter: 112 nm) and an average opening ratio of 28.4%.

On the formed Al-made porous membrane 42, a polycrystalline Si layer 43 of 50 nm thickness serving as an n⁺-type layer was formed according to the plasma CVD method under the conditions that the temperature of the substrate was 500° C., that the materials gases were PH₃, SiH₄ and H₂, and that the RF power was 50 W. In this procedure, the openings of the Al-made porous membrane 42 were filled with the n⁺-type polycrystalline Si layer 43.

Finally, a light-incident side electrode 44 was formed on the polycrystalline Si layer 43 serving as the n⁺-layer to produce a solar cell.

The solar cell thus produced in Example 2 was evaluated in the same manner as in Example 1. As a result, it showed as good a photoelectric conversion efficiency as 5.8%. The same procedures were repeated except for changing the material of the light-incident side electrode from Al to other metal, and as a result it was verified that the effect of the present invention was also obtained in those cases.

### Example 3

### Amorphous Si Solar Cell

In the present example, an Au-made porous membrane was formed in an n-layer in a pin-junction of amorphous Si. The following example describes an Au-made porous membrane produced by etching an Au membrane.

FIG. 15 shows a schematic sectional view of an amorphous Si solar cell according to an embodiment of the present invention. The process of producing the amorphous Si solar cell in Example 3 is explained below without drawings.

First, on a transparent quartz substrate 50, a back electrode 51 mainly comprising tin oxide (SnO₂) was formed at about 500° C. in a thickness of about 500 nm to 800 nm by means of a thermal CVD apparatus. The transparent electrode thus formed had a surface of moderately rough texture. Subsequently, a p-type amorphous Si layer 52 of 20 nm thickness was formed on the back electrode 51 from SiH₄ and Hgases as the main materials and B₂H₆ as the doping gas by means of a plasma CVD apparatus.

Subsequently, an i-type amorphous Si layer 53 and an n-type amorphous Si layer 54 are formed by means of the plasma CVD apparatus in the same manner as the p-type amorphous Si layer 52. The i-type amorphous Si layer 53 of 300 nm thickness and the n-type amorphous Si layer 54 of 30 nm thickness were successively formed by accumulation from SiH₄ gas and PH₃-SiH₄ mixed gas, respectively, to produce a pin-type photoelectric conversion layer.

The composite consisting of the quartz substrate 50, the back electrode 51, the p-type amorphous Si layer 52, the i-type amorphous Si layer 53 and the n-type amorphous Si layer 54 was taken out of the vacuum chamber, and then Au was vapor-deposited thereon to form an Au-made porous membrane 55 of 30 nm thickness. Further, an i-ray positive-working thermosetting resist was spin-coated to form a resist layer of 150 nm thickness.

Onto the formed resist layer, a fine relief pattern corresponding to the openings proposed in the present invention was transferred by use of a stamper as the mold. In Example 3, a quartz plate was fabricated by means of electron beam-lithography to prepare the stamper. On the surface of the stamper, holes of 120 nm depth and of 320 nm diameter were aligned in the closest packing arrangement with a period of 500 nm.

In the process of producing the solar cell proposed in the present invention, there are no particular restrictions on the material of the stamper and on the method of forming the fine relief pattern on the stamper. For example, it is possible to produce the stamper by use of fine particles in the manner described above or by use of block copolymer. The surface of the stamper was then coated with a fluorine-containing releasing agent such as perfluoro-polyether, to lower the surface energy of the stamper enough to improve the releasability.

Successively, the stamper was pressed onto the above resist layer by use of a heater plate press under the conditions that the substrate temperature was 125° C. and the stamping pressure was 6.7 kgf/cm², and then cooled for 1 hour to room temperature. When the stamper was released vertically, it was found that the pattern of the stamper was reversely transferred onto the resist layer. In this way, a periodical opening resist pattern was formed. The resist pattern was constituted of periodically arranged pillars of 320 nm diameter. The embodiment of this example is not restricted to the thermal nano-imprinting process described above, and the functions of the resultant solar cell are not impaired even if the same pattern is formed by use of other imprinting techniques such as photo-imprinting and soft imprinting.

The Au-made porous membrane 55 was then etched for 45 seconds through the obtained resist pattern as a mask by means of an ion beam milling apparatus under the conditions of Ar gas: 5 sccm, ion source power: 500 V and 40 mA.

The above procedures gave an Au-made porous membrane 55 of 30 nm thickness provided with openings having an average opening area of 8.0×10⁻² μm² (opening diameter: 320 nm) and an average opening ratio of 37.1%. In the present example, the obtained metal porous membrane was used as an electrode of the solar cell.

Further, on the formed Au-made porous membrane 55, an n-type amorphous Si layer 56 of 50 nm thickness serving as the n-layer was formed by accumulation in the above manner. In this procedure, the openings of the Au-made porous membrane 55 were filled with the n-type amorphous Si layer 56.

After a back electrode was provided, the obtained solar cell was evaluated on the conversion efficiency in the same manner as in Example 1. As a result, it showed as good a photoelectric conversion efficiency as 4.8%. The same procedures were repeated except for changing the material of the light-incident side electrode from Au to other metal, and as a result it was verified that the effect of the present invention was also obtained in those cases.

### Example 4

In the present example, SiO₂ was accumulated to form a refractive index adjusting layer 63 on the mono-crystalline solar cell produced in Example 1. Further, a rough structure 64 consisting of minute cones at a pitch of 200 nm was provided on the surface of the adjusting layer 63 so as to prevent the Fresnel reflection between air and the refractive index adjusting layer 63.

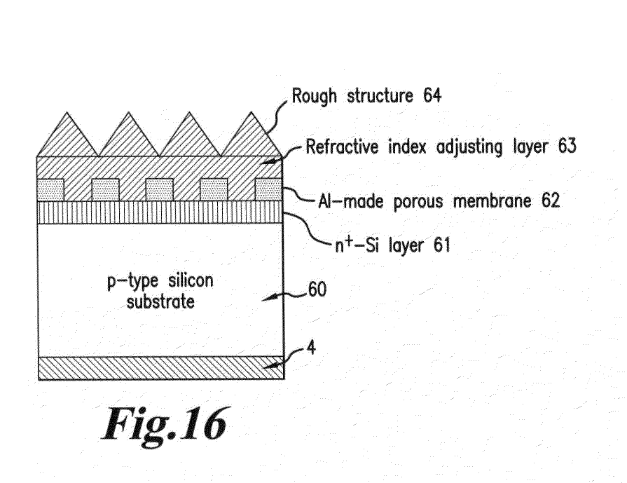

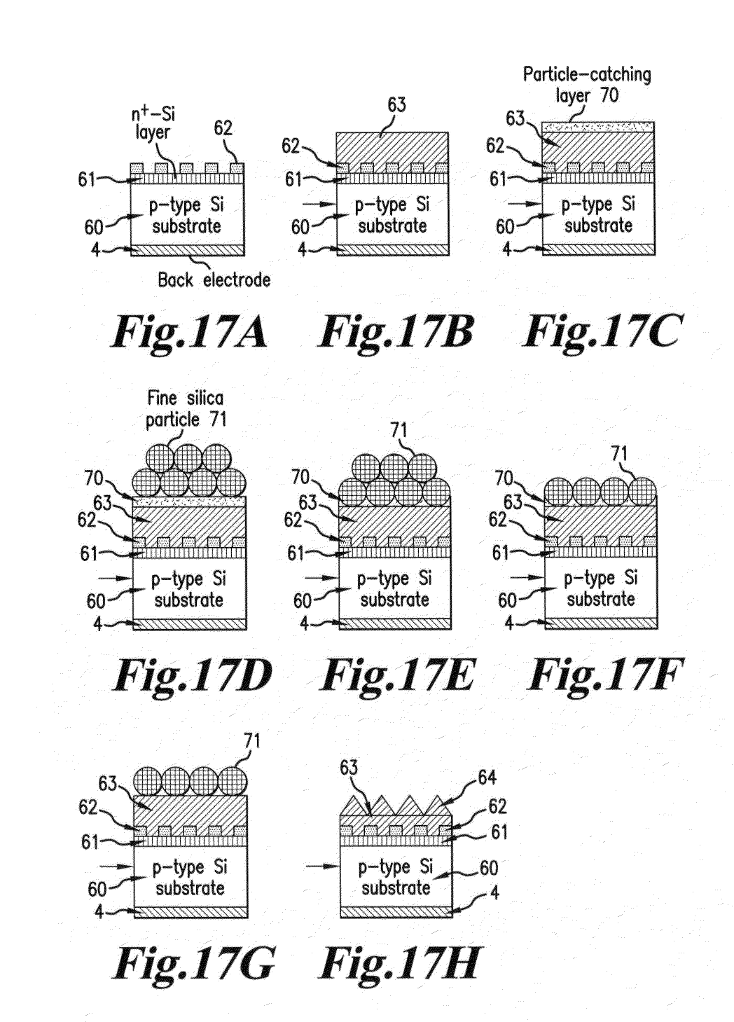

FIG. 16 shows a schematic sectional view of a monocrystalline solar cell comprising a refractive index adjusting layer and a rough structure according to an embodiment of the present invention. Further, FIG. 17 shows schematic sectional views illustrating a method of producing the surface rough structure on the solar cell according to an embodiment of the present invention.

First, similarly to the solar cell produced in Example 1, an n⁺-Si layer 61 was formed on a p-type silicon substrate 60. After that, an Al-made porous membrane 62 having openings at a predetermined interval pitch was formed on the n⁺-Si layer 61. On the bottom surface of the p-type silicon substrate 60, a back electrode 4 was provided, as shown in FIG. 17(a).

Next, as shown in FIG. 17(b), a refractive index adjusting layer 63 of 300 nm thickness was formed from SiO₂ by the CDV method so as to cover the Al-made porous membrane 62. In this procedure, the openings of the Al-made porous membrane 62 were filled with the refractive index adjusting layer 63.

Further, as shown in FIG. 17(c), a resist (THMR IP3250 [trademark], manufactured by Tokyo Ohka Kogyou Co., Ltd.) capable of halfmicron resolution was spin-coated on the refractive index adjusting layer 63 at 2000 rpm for 35 seconds to form a particle-catching layer 70, which was then baked on a hot-plate at 110° C. for 90 seconds. The particle-catching layer 70 thus formed on the refractive index adjusting layer 63 was found to have a thickness of 55 nm and to be suitable for capturing only a monolayer of particles having an average diameter of 200 nm.

Thereafter, the surface of the catching layer 70 was hydrophilized by means of an etching apparatus (manufactured by SAMCO Inc.). The etching was carried out for 5 seconds by use of oxygen gas under the conditions of flow rate: 30 sccm, pressure: 0.1 Torr and power: 100 W.

Furthermore, as shown in FIG. 17(d), a water dispersion of fine silica particles 71 (PL-13[trademark], manufactured by Fuso Chemical Co., Ltd., average diameter of silica particles: 200 nm) was spin-coated at 1000 rpm for 60 seconds to form a multiparticle layer consisting of two or three sub-layers of the fine silica particles 71.

Thereafter, as shown in FIG. 17(e), the p-type silicon substrate 60 was baked on a hot plate at 210° C. for 30 minutes, so that the fine silica particles 71 only in the bottom of the multiparticle layer were fixed on the silicon substrate 60.

Subsequently, as shown in FIG. 17(f), the p-type silicon substrate 60 was subjected to ultrasonic washing in water for 10 minutes, and then the water was drained out. After pure water was again introduced, the ultrasonic washing was again carried out for 1 minute to remove the fine silica particles 71 not fixed on the silicon substrate 60. The section of the resultant substrate 60 was observed by SEM, and consequently it was found that the fine silica particles 71 were partly buried in the particle-catching layer 70 and aligned in a monoparticle layer.

Successively, as shown in FIG. 17(g), the particle-catching layer 70 was removed by dry etching for 1 minute by use of O₂ gas under the conditions of flow rate: 30 sccm, pressure: 0.01 Torr and power: 100 W. The section of the resultant substrate 60 was observed by SEM, and consequently it was verified that the particle-catching layer 70 filling in the gaps among the fine silica particles 71 was removed from the surface of the p-type silicon substrate 60.

Still further, as shown in FIG. 17(h), the refractive index adjusting layer 63 was fabricated by dry etching for 8 minutes by use of CF₄ gas under the conditions of flow rate: 30 sccm, pressure: 0.01 Torr and power: 100 W. The section of the resultant adjusting layer 63 was observed minutely by SEM, and consequently it was verified that, while the fine silica particles 71 were subjected to slimming by etching, the surface of the refractive index adjusting layer 63 was carved to form convexes or concaves and thereby to form a fine rough structure 65.

The produced solar cell was evaluated on the photoelectric conversion efficiency. As a result, it showed as good a conversion efficiency as 7.6%. The same procedures were repeated except for changing the material of the light-incident side electrode from Au to other metal, and as a result it was verified that the effect of the present invention was also obtained in those cases.

While certain embodiments have been described, these embodiments have been presented by way of example only, and are not intended to limit the scope of the invention. Indeed, the novel methods and systems described herein may be embodied in a variety of other forms; furthermore, various omissions, substitutions and changes in the form of the methods and systems described herein may be made without departing from the spirit of the invention. The accompanying claims and their equivalents are intended to cover such forms or modifications as would fail within the scope and sprit of the invention.

### BRIEF DESCRIPTION OF THE NUMERALS

1: solar cell

2: light-incident side electrode

3: metal porous membrane

4: back electrode

5: photoelectric conversion layer

6: refractive index adjusting layer

7: anti-reflective coating

8: opening

20: p-type silicon substrate

21: n⁺-layer

22: acid-resistant resin

30: Al-made membrane

31: resist layer

32: fine silica particle

33: SOG layer

34: refractive index adjusting layer

40: p-type silicon substrate

41: n⁺-layer

42: Al-made porous membrane

43: polycrystalline Si layer

44: light-incident side electrode

50: quarts substrate

51: back electrode

52: p-type amorphous Si layer

53: i-type amorphous Si layer

54: n-type amorphous Si layer

55: Au-made porous membrane

56: n-type amorphous Si layer

60: p-type silicon substrate

61: n⁺-Si layer

62: Al-made porous membrane

63: refractive index adjusting layer

64: rough structure

70: particle-catching layer

71: fine silica particle

1. A solar cell comprising a laminate of a photoelectric conversion layer, a metal porous membrane and a refractive index adjusting layer, wherein
said metal porous membrane is positioned on the light-incident side,
said metal porous membrane is directly in contact with said photoelectric conversion layer,
said metal porous membrane has plural openings bored though said membrane,
said refractive index adjusting layer covers at least a part of the surface of said metal porous membrane and of the inner surfaces of said openings, and
said refractive index adjusting layer has a refractive index of 1.35 to 4.2 inclusive.

2. The solar cell according to claim 1, wherein there are breaks in a part of said metal porous membrane.

3. The solar cell according to claim 1, wherein the light-incident side top surface of said refractive index adjusting layer is provided with an anti-reflective coating having plural convexes or concaves neighboring each other.

4. The solar cell according to claim 1, wherein each of said openings occupies an area of 80 nm² to 0.8 μm² inclusive on average and the opening ratio thereof is in the range of 10% to 66% inclusive.

5. The solar cell according to claim 1, wherein said metal porous membrane has a thickness of 10 nm to 200 nm inclusive.

6. The solar cell according to claim 1, wherein said photo-electric conversion layer at least includes p-type and n-type semiconductors, a Schottky barrier junction or a PIN junction.

7. The solar cell according to claim 1, wherein said photo-electric conversion layer at least includes p-type and n-type silicon selected from the group consisting of monocrystalline Si, polycrystalline Si and amorphous Si.

8. The solar cell according to claim 1, wherein said metal porous membrane is made of a material selected from the group consisting of Al, Ag, Au, Pt, Ni, Co, Cr, Cu and Ti.
